(19) United States
(12) Patent Application Publication
(10) Pub. No.: US 2024/0349467 A1
(43) Pub. Date: Oct. 17, 2024

(54) RADIO FREQUENCY AND ELECTROMAGNETIC INTERFERENCE SHIELDING WINDOW SHADE

(71) Applicant: Swift Textile Metalizing LLC, Bloomfield, CT (US)

(72) Inventors: Michael S. Matysek, Bloomfield, CT (US); Adam R. Allard, Bloomfield, CT (US); Alexander T. Smith, Knoxville, TN (US)

(21) Appl. No.: 18/633,990

(22) Filed: Apr. 12, 2024

Related U.S. Application Data
(60) Provisional application No. 63/459,496, filed on Apr. 14, 2023.

(51) Int. Cl. H05K 9/00; E06B 9/42; E06B 9/58

(52) U.S. Cl. CPC H05K 9/0005; E06B 9/42; E06B 9/58; H05K 9/0088; E06B 2009/588

(57) ABSTRACT

The present disclosure relates to a radio frequency and electromagnetic interference shielding window shade comprising: a roller tube comprising a roller shade clutch and an end plug connected through a cylindrical body, the clutch configured to rotate the roller tube; a shade material extending between a first end attached to the roller tube and a second end extending away from the roller tube, wherein the shade material is configured to rotate about the cylindrical body of the roller tube to roll or unroll the shade, the shade material comprising a shielding layer attached to a side of a base layer and comprising a conductive material, wherein unrolling the shade material from the roller tube covers at least a portion of a window, thereby shielding the window from the radio frequency and electromagnetic interference at an attenuation of at least about 30 dB at a frequency of at least about 10 KHz.

### CROSS-REFERENCE SECTION

This Application claims priority to U.S. Provisional Application No. 63/459,496, filed on Apr. 14, 2023, which is incorporated by reference herein in its entirety for all purposes.

### BACKGROUND

Radiofrequency (RF) and electromagnetic (EM) interference shielding is critical in protecting electronic devices as well as confidential information from electronic eavesdropping and theft. Mitigating unwarranted signals entering or emanating from equipment or facilities is critical in operations security. If such confidential information is accessed or intercepted, the information may be used to gain access to critical systems and information, such as for the government, commercial, and individual entities.

For example, the Government Facilities Sector (GFS) includes more than 900,000 constructed assets owned or operated by the Federal Government alone. Assets owned by the 56 states and territories, 3,031 counties, 85,973 local governments, and 566 federally recognized tribal nations are also within the scope of the GFS. Additionally, the GFS includes the subsectors of National Monuments and Icons and Education Facilities. Information being compromised from any of the critical infrastructure sectors of the GFS, including physical or virtual assets, systems, and networks, would have a debilitating effect on national security, national economic security, and national public health or safety. Further, vulnerable commercial/civilian sectors which support national and global economic health include the chemical, commercial facilities, critical manufacturing, energy, materials, nuclear reactor, and waste sectors.

While technology has been developed to provide roofs and walls with RF/EM shielding materials, windows are often left vulnerable because they are hard to protect, particularly while maintaining the functionality of the window. Glass coatings are problematic because they generally do not provide adequate protection against ultraviolet radiation, a primary function of windows. Also, to protect existing window structures, windows have to be completely replaced. Secondly, such coatings can leave the glass susceptible to corrosion as many of the metals are not resistant to the environment. Further, if such coating corrodes or breaks, it is necessary to replace the entire window, which is cost prohibitive. Lastly, such coatings are irreversible, which does not offer a mechanism to control the RF/EM interference shielding. Window films may require application to the interior and exterior window glass to be effective, and generally have a lower shielding effectiveness across a fairly narrow frequency range. Such films do not have the ability to completely encapsulate or shield a window due to gaps between the edge of the film and the rest of the shielded room/enclosure. Window films are susceptible to damage caused during glass cleaning and to damage from natural elements/environmental conditions. Curtains are a potential option to provide RF/EM shielding, but are limited in shielding effectiveness due to gaps between curtains and windows. The gaps inherent to window films and curtains are a significant source of RF/EM signal leakage or exposure.

RF/EM shielding technologies are needed that can be readily applied to existing window structures, are durable and replaceable, while having a control mechanism to turn the protection on and off.

### SUMMARY

According to one aspect of the subject matter described in this disclosure, a radio frequency and electromagnetic interference shielding window shade is provided. The radio frequency and electromagnetic interference shielding window shade includes a roller tube having a roller shade clutch and an end plug connected through a cylindrical body, where the clutch is configured to rotate the roller tube. The shade material may extend between a first end attached to the roller tube and a second end extending away from the roller tube. The shade material may be configured to rotate about the cylindrical body of the roller tube to roll or unroll the shade.

A shade material may include a base layer and a shielding layer attached to a side of the base layer and containing a conductive material. A shade material may include a shielding layer. In some embodiments, a shade material may include multiple shielding layers and multiple base layers. For example, a shade material may include a base layer sandwiched between two conductive layers. A shade material may include a conductive layer sandwiched between two base layers. A shade material may include iterative layers of a base layer contacting a conductive layer. Unrolling the shade material from the roller tube may cover at least a portion of a window, thereby shielding the window from the radio frequency electromagnetic interference at an RF attenuation of at least 30 dB at a frequency of at least 10 KHz.

The present disclosure relates to a radio frequency and electromagnetic interference shielding window shade containing a roller tube containing a roller shade clutch and an end plug connected through a cylindrical body. The clutch may be configured to rotate the roller tube. The radio frequency and electromagnetic interference shielding window shade may include a shade material extending between a first end attached to the roller tube and a second end extending away from the roller tube, wherein the shade material is configured to rotate about the cylindrical body of the roller tube to roll or unroll the shade. The shade material may contain a shielding layer attached to a side of a base layer and containing a conductive material. In some embodiments, unrolling the shade material from the roller tube may cover at least a portion of a window, thereby shielding the window from radio frequency and electromagnetic interference at an attenuation of at least about 30 dB at a frequency of at least about 10 KHz.

The shade material may further include at least one of a plurality of base layers and a plurality of shielding layers. The shade material may further include a second shielding layer, wherein the base layer is sandwiched between the shielding layer and the second shielding layer. The shade material may further include a second base layer, wherein the shielding layer is sandwiched between the base layer and the second base layer. In some embodiments, the RF attenuation ranges from about 30 dB to about 120 dB and the frequency ranges from about 10 KHz to about 100 GHz. The base layer may include a nylon 6, a nylon 66, a polyester, a polyethylene, a polyurethane, a fluorocarbon rubber, a viton, a carbon fiber, and combinations thereof. The conductive material may include an intrinsically conductive polymer, a metal, a carbon, a metal oxide, a polyaniline, a graphene, a carbon nanotube, a silver, a nickel, a copper, and a combination thereof. The radio frequency and electromagnetic interference shielding window may further contain a pass-through plate positioned directly below the roller tube. The pass-through plate may contain a horizontal flat plate spanning a length and a width of the roller tube. The pass-through plate may contain a slot configured to permit passage of the shade material as it unrolls from the roller tube to extend away from the roller tube, thereby covering at least the portion of the window. The radio frequency and electromagnetic interference shielding window may further contain a conductive gasket incorporated into the slot of the pass-through plate. In some embodiments, the conductive gasket may include a polymer containing silicone, polyethylene, a natural rubber, a neoprene, a nitrile, a fluoropolymer, a PTFE, a polyether ether ketone, a cellulose, a mylar polyester, a polycarbonate, a polytetrafluoroethylene, and combinations thereof. The conductive gasket may include a metal containing silver, copper, gold, nickel, nickel-graphite, silver coated copper, silver coated aluminum, aluminum, silver coated glass, nickel coated aluminum, nickel coated copper, nickel coated glass, and combinations thereof. The conductive gasket may be configured to make contact with the shade material as it moves towards and away from roller tube. The conductive gasket may have a shape containing a c-shape, a bell-shape, a u-shape, a cylindrical shape, a cube, a pyramid, a prism, a cone, a sphere, and combinations thereof.

According to some embodiments, the present disclosure relates to a system for shielding a window from a radio frequency and electromagnetic interference, the system containing a radio frequency and electromagnetic interference shielding window shade containing a roller tube containing a roller shade clutch and an end plug connected through a cylindrical body, where the clutch is configured to rotate the roller tube. The radio frequency and electromagnetic interference shielding window shade may contain a shade material extending between a first end attached to the roller tube and a second end extending away from the roller tube, wherein the shade material may be configured to rotate about the cylindrical body of the roller tube to roll or unroll the shade. The shade material may contain a shielding layer attached to a side of a base layer and also contain a conductive material. The system for shielding a window from a radio frequency and electromagnetic interference may contain a channel conductive fabric gasket configured to fit into at least one side channel of the window. In some embodiments, unrolling the shade material from the roller tube covers at least a portion of a window, thereby shielding the window from the radio frequency and electromagnetic interference at an RF attenuation of at least about 30 dB at a frequency of at least about 10 KHz.

The system for shielding the window from radio frequency and electromagnetic interference may further contain two channel conductive fabric gaskets configured to fit into each side channel of the window. The channel conductive fabric gasket may include a polymer containing silicone, polyethylene, a natural rubber, a neoprene, a nitrile, a fluoropolymer, a PTFE, a polyether ether ketone, a cellulose, a mylar polyester, a polycarbonate, a polytetrafluoroethylene, and combinations thereof. The channel conductive fabric gasket may include a metal containing silver, copper, gold, nickel, nickel-graphite, silver coated copper, silver coated aluminum, aluminum, silver coated glass, nickel coated aluminum, nickel coated copper, nickel coated glass, and combinations thereof.

The system for shielding the window from radio frequency and electromagnetic interference may further contain a sill conductive fabric gasket configured to fit into a sill of the window. The sill conductive fabric gasket may include a polymer containing silicone, polyethylene, a natural rubber, a neoprene, a nitrile, a fluoropolymer, a PTFE, a polyether ether ketone, a cellulose, a mylar polyester, a polycarbonate, a polytetrafluoroethylene, and combinations thereof. The sill conductive fabric gasket may include a metal containing silver, copper, gold, nickel, nickel-graphite, silver coated copper, silver coated aluminum, aluminum, silver coated glass, nickel coated aluminum, nickel coated copper, nickel coated glass, and combinations thereof. The sill conductive fabric gasket may include a length ranging from about 6 inches to about 120 inches. The sill conductive fabric gasket may include a width ranging from about 1 inch to about 12 inches. The sill conductive fabric gasket may include thickness ranging from about 0.1 inch to about 6 inches. The channel conductive fabric gasket may include a length ranging from about 6 inches to about 120 inches. The channel conductive fabric gasket may include a width ranging from about 1 inch to about 12 inches. The channel conductive fabric gasket may include a thickness ranging from about 0.1 inch to about 6 inches. The base layer may include a nylon 6, a nylon 66, a polyester, a polyethylene, a polyurethane, a fluorocarbon rubber, a viton, a carbon fiber, and combinations thereof. The conductive material may include an intrinsically conductive polymer, a metal, a carbon, a metal oxide, a polyaniline, a graphene, a carbon nanotube, a silver, a nickel, a copper, and a combination thereof. The RF/EM attenuation may range from about 30 dB to about 120 dB. The frequency may range from about 10 KHz to about 100 GHz. The shade material may further include at least one of a plurality of base layers and a plurality of shielding layers. The system for shielding the window from the radio frequency and electromagnetic interference may include a pass-through plate positioned directly below the roller tube. The pass-through plate may contain a horizontal flat plate spanning a length and a width of the roller tube and a slot configured to permit passage of the shade material as it unrolls from the roller tube to extend away from the roller tube, thereby covering at least a portion of the window. In some embodiments, the shade material may further include a second base layer, wherein the shielding layer may be sandwiched between the base layer and the second base layer. The system for shielding the window from the radio frequency and electromagnetic interference may include a steel rod attached to a bottom end of the shade material. The system may include an indicator configured to interact with the steel rod as the shade material extends away from the roller tube to cover the window and to visually indicate coverage of the window by the shade material.

Additional features and advantages of the present disclosure are described in, and will be apparent from, the detailed description of this disclosure.

### BRIEF DESCRIPTION OF THE DRAWINGS

The disclosure is illustrated by way of example, and not by way of limitation, in the figures of the accompanying drawings in which like reference numerals are used to refer to similar elements. It is emphasized that various features may not be drawn to scale and the dimensions of various features may be arbitrarily increased or reduced for clarity of discussion.

FIG. 1 is an exploded-view of a known window roller shade, in accordance with some embodiments.

FIG. 2 illustrates various perspectives of a known side and sill channel having additional interior channels/structures to accommodate synthetic pile inserts, in accordance with some embodiments.

FIG. 3A illustrates a top view of a pass-through plate and a front view of a roller, in accordance with some embodiments.

FIG. 3B illustrates a bottom view of the pass-through plate of FIG. 3A and a front view of the roller form FIG. 3A, in accordance with some embodiments.

FIG. 4 illustrates various view of various gaskets, shade materials, and hardware components of a radio frequency and electromagnetic interference shielding window shade, in accordance with some embodiments.

FIG. 5 provides three graphs showing the shielding performance and compression dynamics of a shade material for a radio frequency and electromagnetic interference shielding window shade, in accordance with some embodiments.

FIG. 6 illustrates a full front view, upper right view, and lower right view of a radio frequency and electromagnetic interference shielding window shade in a closed position, in accordance with some embodiments.

FIG. 7. Illustrates an upper right view, a lower right view, and an inside view of a radio frequency and electromagnetic interference shielding window shade in an open position, in accordance with some embodiments.

FIG. 8 illustrates an inverted view and a top view of a radio frequency and electromagnetic interference shielding window shade with the top and front fascia removed, in accordance with some embodiments.

FIG. 9 illustrates a top view of a radio frequency and electromagnetic interference shielding window shade with the top and front fascia removed and an unobstructed view of a pass-through plate, in accordance with some embodiments.

FIG. 10 illustrates a top view of a pass-through plate assembly of a radio frequency and electromagnetic interference shielding window shade, in accordance with some embodiments.

### DETAILED DESCRIPTION

The present disclosure relates to radio frequency (RF) and electromagnetic (EM) interference shielding window shade. A disclosed RF/EM interference shielding window shade may shield a window from a radio frequency and electromagnetic interference at an RF attenuation of at least about 30 dB at a frequency of at least about 10 KHz, whereas generally available window shades do not. A disclosed system for shielding a window from radio frequency and electromagnetic interference may include an RF/EM interference shielding window shade as well as various conductive fabric gaskets that fit in channels and sills of a window, advantageously increasing RF/EM interference of the window with respect to a known window not containing these window shade and gasket components.

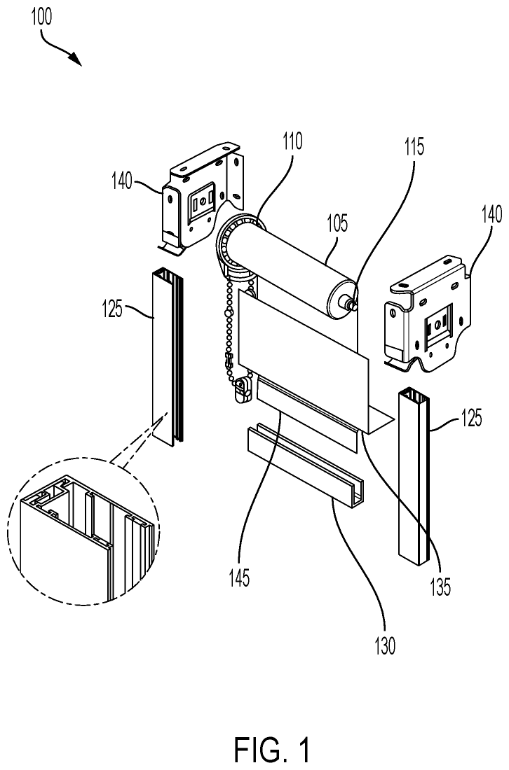

FIG. 1 is an exploded view of a known window shade 100 that does not provide RF/EM interference shielding. As is shown in FIG. 1, the window shade 100 may include a roller tube 105 having a roller shade clutch 110 and an end plug 115 connected through a cylindrical body. The clutch 110 is configured to rotate the roller tube 105. The shade material 120 may extend between a first end attached to the roller tube 105 and a second end extending away from the roller tube 105. The shade material 120 may be configured to rotate about the cylindrical body of the roller tube 105 to roll or unroll the shade material 120.

A known window shade 100, such as shown in FIG. 1, may include one or more side channels 125 each having pile inserts, a sill channel 130 with pile inserts, one or more non-handed fascia brackets 140, fascia 135, and a standard heat-sealed pocket 145 for aluminum hem bar

In general, known window shade 100 designs provide light filtering, light blocking, privacy, and aesthetics. A disclosed RF/EM interference shielding window shade may include each of the features of known window shades while advantageously being able to block and/or contain RF signals and EM interference. Minimizing the possibility of an RF signal leak or interception is also a critical capability of disclosed RF/EM interference shielding window shades. For the disclosed RF/EM interference shielding window shade to accomplish this function, it may be designed to have minimal points of RF/EM leakage. For example, by including a conductive ‘seal’ by incorporating a conductive (e.g., electrical, thermal) material into shade components.

Known window shades 100 are not designed to block RF/EM signals and would not be capable of blocking RF/EM signals without significant design changes. For example, there are gaps in known window shade 100 designs found at numerous points within the side channels 125 and sill channels 130, the shade material, in and around the roller assembly, in the valance, and in the fascia 135. Each of these gaps in known window shades 100 leak RF/EM signals. Disclosed designs achieve an effective conductive barrier by minimizing and/or eliminating these gaps by incorporating RF/EM shielding materials.

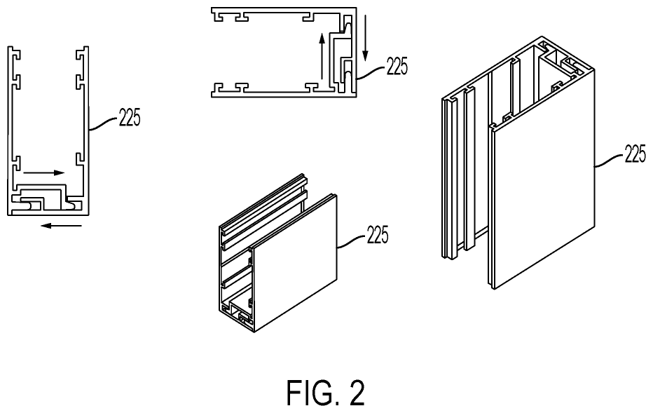

FIG. 2 depicts various perspectives of a side channel 225 having synthetic pile inserts of a known shade. Known shades are limited in that they contain additional ridges and/or profiles in the interior of their channels that contain non-conductive gasketing for light blocking purposes. Each of these additional ridges and/or profiles are areas that can let RF/EM signals through the window shade. Disclosed RF/EM shielding window shades herein prevent these RF/EM signal leaks.

Disclosed RF/EM interference shielding window shades may provide RF/EM shielding in a secure room, such as in a government sensitive compartmented information facility (SCIF) that requires a complete RF/EM shielding barrier. Some RF/EM signal shielding may be accomplished by incorporating conductive materials on walls, behind walls, and or between layers of drywall. However, in the event that a room includes a window, said window is a source of RF/EM signal leakage, which may be addressed with the disclosed shades. For a roller shade to be incorporated into this type of space, the shade may be ‘tied in’ with the walls to maintain a conductive barrier. The disclosed RF/EM interference shielding window shade may accomplish such a shielding barrier with a gasket behind side/sill channels and/or a pass-through plate. In some embodiments, a backing gasket may be tied into other conductive shielding materials in a room. In some embodiments, the disclosed RF/EM interference shielding window shade includes a custom backing gasket behind side/sill channels, metal channels void of non-conductive materials (e.g., anodizing, paint, powder coat, etc.), conductive gasketing inside shade channels with pressure between conductive gaskets and conductive shade materials. Including such features in the disclosed RF/EM interference shielding window shades may provide for a fully conductive seal from a backing gasket to side/sill channels, from side/sill channels to conductive gasketing, and from conductive gasketing to conductive shade material.

The disclosed RF/EM shielding window shade may include each of the components known for the window shade from FIGS. 1 and 2, but may include additional features that provide RF/EM shielding. The RF/EM interference shielding window shade may include custom pieces (e.g., pass-through plates/slot) that create a barrier that eliminates a significant portion of RF/EM signal leaks through which a signal may escape between the side/sill channels and the roller mechanism, as well as associated components (e.g., pull chain, fascia, valance). The RF/EM interference shielding window shade may exclude components of known shades, including ‘ridges’ inside typical shade side/sill channels, which may provide a suitable area for conductive gasketing or other shielding materials to eliminate gaps and create a conductive plane. In some embodiments, a disclosed RF/EM interference shielding window shade may include manually operated as well as motorized roller shades.

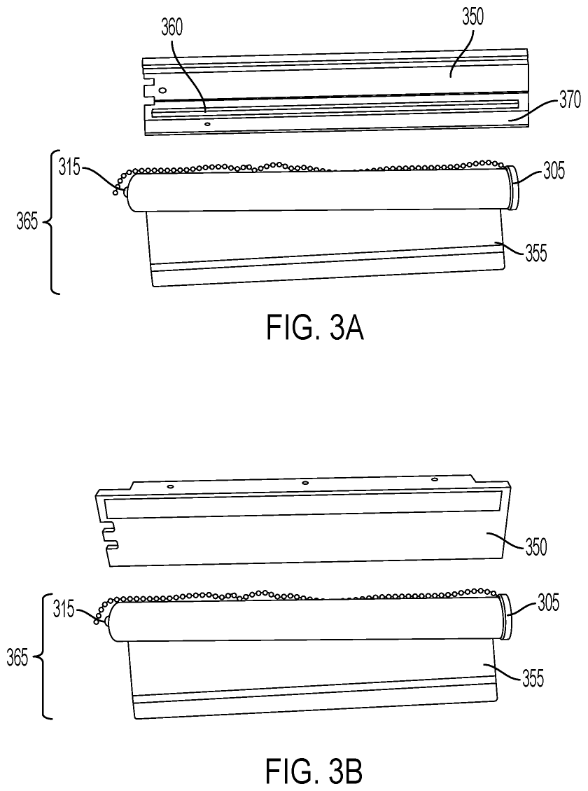

FIGS. 3A and 3B illustrates various views of a disclosed RF/EM shielding window shade 365 and a pass-through plate 350. Pass-through plates 350 generally contain a slot 370, milled into the pass-through plate 350, that spans the length and width of the roller tube 305. The slot 370 permits passage of a disclosed shade material 355 as it unrolls from the roller tube 305 to extend away from the roller tube 305, thereby covering at least a portion of a window. With known window shades, there is RF/EM leakage through the slot 370 because there are gaps between a known window shade and the slot. In disclosed systems, the pass-through plate 350 includes a conductive gasket 360 that prevents RF/EM leakage by sealing any space between the disclosed shade material 355 and the slot 370. The conductive gasket 360 disclosed herein synergistically functions with conductive gasketing contained in side and sill channels to create a conductive envelop that significantly reduces RF/EM signal leakage.

The conductive gasket may include a base material and a conductive material. The base material of the conductive gaskets 360 may include elastomers, thermoplastic polymers, cellulose fiber, carbon, fiberglass, composites, thermoset polymers, and basalt. Different combinations of base materials and conductive materials can change the product performance to target shielding attenuations for various frequency ranges. For example, having various base materials may advantageously provide different mechanical advantages, such as, higher tensile strength, elongation and temperature degradation resistance, etc. The base material of the conductive gasket 360 may include a polymer including a nylon 6, a nylon 66, a polyester, a polyethylene, a polyurethane, a fluorocarbon rubber, a viton, a carbon fiber, and combinations thereof. The base material may include a polymer including a silicone, a polyethylene, a natural rubber, a neoprene, a nitrile, a fluoropolymer, a polytetrafluoroethylene (PTFE), a polyether ether ketone, a cellulose, a mylar polyester, a polycarbonate, a polytetrafluoroethylene, and combinations thereof. The conductive material of the conductive gasket 360 may include an intrinsically conductive polymer, a metal, a carbon, a metal oxide, a polyaniline, a graphene, a carbon nanotube, a silver, gold, a nickel, a nickel-graphite, a copper, a silver coated copper, a silver coated aluminum, aluminum, a silver coated glass, a nickel coated aluminum, a nickel coated copper, and a combination thereof. The conductive gasket 360 may be configured to make contact with the shade material 355 as it moves towards and away from a roller tube, thereby preventing RF/EM leakage through the pass-through plate as the position of the shade material is adjusted. The conductive gasket 360 may have any general shape, such as by having a cross-section that is a c-shape, a bell shape, a u-shape, a circle, a triangle, any polygon, and combinations thereof.

As shown in FIG. 3A, besides incorporating gaskets 360 on the slot 370 of the pass-through plate 350, the disclosed RF/EM shielding window shade 365 may include the shade material 355 that also shields the window from RF/EM interference at an attenuation of at least about 30 dB at a frequency of at least about 10 KHz. In disclosed embodiments, the RF/EM shielding window shade 365 may include a shade material 355 having a base layer and a shielding layer attached to a side of the base layer and containing a conductive material. The shade material 355 may include a plurality of base layers and a plurality of shielding layers. For example, the shade material 355 may include from about 1 to about 10 base layers and from about 1 to about 10 shielding layers. The shade material 355 may include about 1 base layer, or about 2 base layers, or about 4 base layers, or about 6 base layers, or about 8 base layers, or about 10 base layers, where about includes plus or minus 1 base layer. The shade material may include about 1 shielding layer, or about 2 shielding layers, or about 4 shielding layers, or about 6 shielding layers, or about 8 shielding layers, or about 10 shielding layers, where about includes plus or minus 1 shielding layer.

The shade material 355 may include the base layer and the shielding layer attached to a side of the base layer, where the shielding layer may contain a conductive material. In some embodiments, the shade material 355 may include multiple shielding layers and multiple base layers. For example, the shade material 355 may include a base layer sandwiched between two shielding layers. The shade material 355 may include a shielding layer sandwiched between two base layers. The shade material 355 may include iterative layers of the base layer contacting the shielding layer.

In some embodiments, unrolling the shade material 355 of a disclosed RF/EM shielding window shade from a roller tube may cover at least a portion of a window, thereby shielding the window from the radio frequency and electromagnetic interference at an attenuation of at least 30 dB at a frequency of at least 10 KHz. The shade material 355 may shield a window with an RF/EM attenuation that ranges from about 30 decibels (dB) to about 120 dB. For example, the disclosed shade material 355 may provide the window with an RF/EM attenuation of about 30 dB, or about 60 dB, or about 90 dB, or about 120 dB, where about includes plus or minus 15 dB. The shade material 355 may provide a window with an RF/EM attenuation ranging from about 30 dB to about 120 dB at a frequency ranging from about 10 kilohertz (KHz) to about 100 gigahertz (GHz). For example, the shade material 355 may provide a window with an RF/EM attenuation ranging from about 30 dB to about 120 dB at a frequency of about 10 KHz, or of about 100 KHz, or about 1,000 KHz, or about 10,000 KHz, or about 100,000 KHz, or about 1,000,000 KHz, or about 10,000,000 KHz, or about 100,000,000 KHz, or about 1,000,000,000 KHz (or 1 GHz), or about 10,000,000,000 KHz (or 10 GHz), or about 100,000,000,000 KHz (or 100 GHz), where about includes plus or minus any half-way points of the above-described ranges. The ranges of shielding described above may be attenuated by including various aspects of the disclosed RF/EM shielding window shade 365, such as by adjusting the various sizes, shapes, and number of shielding layers in the shade material 355. Additionally, the ranges of shielding may be attenuated by incorporating various conductive gaskets as is described herein into a slot of a pass-through plate 350, in a sill, and in a side channel of the window, as is described in various embodiments of this disclosure.

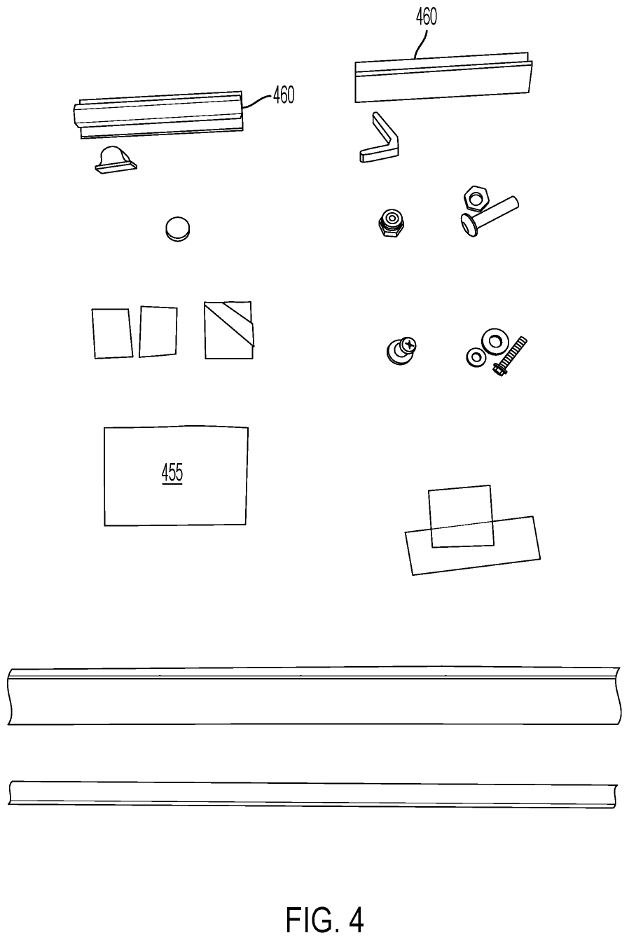

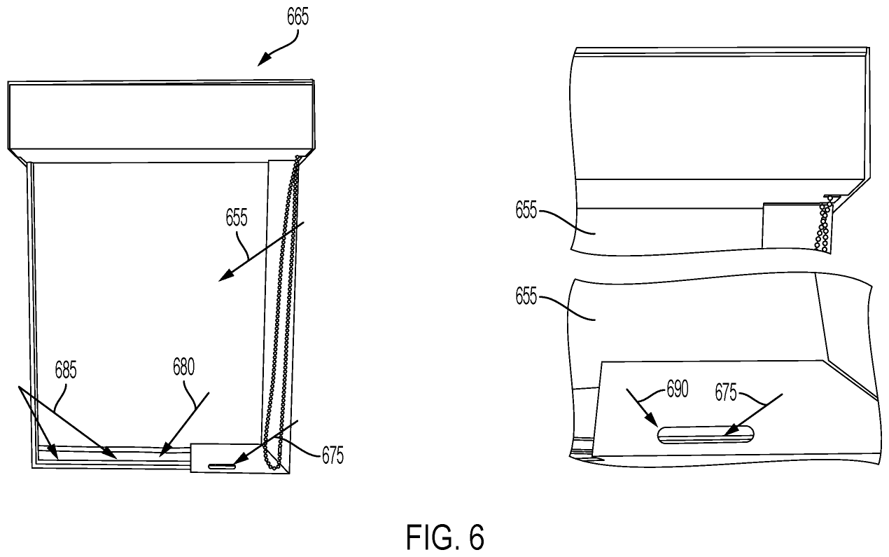

FIG. 4 illustrates various components of an RF/EM interference shielding window shade, in accordance with some embodiments. FIG. 4 includes a variety of hardware; conductive gaskets 460 for pass-through slots, sills, and side channels; shielding materials 455; and laminating material used in disclosed RF/EM interference shielding window shades, such as those depicted in FIGS. 6-10.

According to some embodiments, the RF/EM interference shielding window shades may be part of a system for shielding a window from RF/EM interference. Besides including the RF/EM interference shielding window shade, the system may include additional fabric gaskets that provide additional shielding. For example, the system may include a conductive fabric gasket configured to fit into one or more side channels of the window. The channel conductive fabric gasket may be of any various size and shapes to fit into various side channels of the window. The system may include one conductive channel fabric gasket, two conductive channel fabric gaskets, three conductive channel fabric gaskets, four conductive channel fabric gaskets, five conductive channel fabric gaskets, six conductive channel fabric gaskets, or more, fit into each side channel of the window. The channel conductive fabric gasket may include a polymer comprising silicone, polyethylene, a natural rubber, a neoprene, a nitrile, a fluoropolymer, a PTFE, a polyether ether ketone, a cellulose, a mylar polyester, a polycarbonate, a polytetrafluoroethylene, and combinations thereof. The channel conductive fabric gasket may include a metal comprising silver, copper, gold, nickel, nickel-graphite, silver coated copper, silver coated aluminum, aluminum, silver coated glass, nickel coated aluminum, nickel coated copper, nickel coated glass, and combinations thereof. In some embodiments, the channel conductive fabric gasket may include a length ranging from about 6 inches to about 120 inches. The channel conductive fabric gasket may include a width ranging from about 1 inch to about 12 inches. The channel conductive fabric gasket may include a thickness ranging from about 0.1 inch to about 6 inches. Adding additional channel conductive fabric gaskets may increase the overall RF/EM interference shielding of the disclosed system.

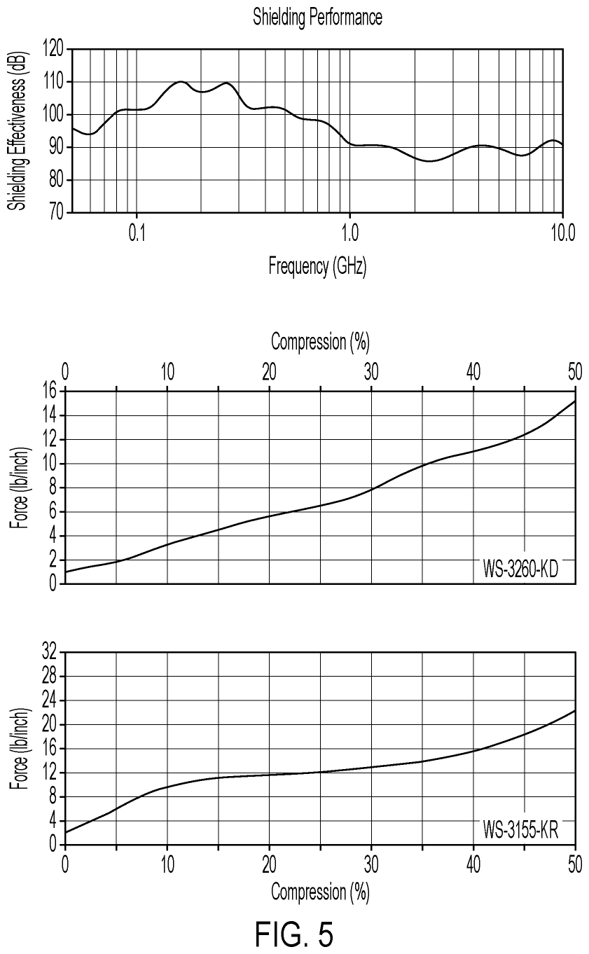

FIG. 5 includes three graphs showing the shielding performance and compression dynamics of an RF/EM shielding gasket for an RF/EM interference shielding window shade. As is shown in FIG. 5, RF/EM shielding materials, including an RF/EM shielding gasket, as disclosed herein, effectively shield against a radio frequency electromagnetic interference. FIG. 5 depicts effective shielding, of disclosed materials, of a number of different types, shapes, profiles, and materials that may be used for gasketing a disclosed RF/EM interference shielding window shade.

FIG. 6 illustrates a full front view, upper right view, and lower right view of a system for shielding a window from RF/EM interference. Disclosed systems may include a shade material 655, gaskets (hidden) fitted into side channels and the sill. In FIG. 6, a steel bar is not visible, but is engaged with magnets. The left side fascia and portion of bottom fascia are left open to show the interior view of these portions. On the upper right view, the shade material 655 is fully exposed and the RF/EM shielding window shade 665 of the system is in the closed position. In some embodiments, a disclosed system may include an indicator 675 configured to visibly indicate when RF/EM shielding is occurring by the RF/EM shielding window shade 665. The indicator 675 may be a magnetic indicator, triggered when magnets 685 located at a bottom of the window interact with a bar 680 (e.g., steel bar) located at a lower end of the shade material 655. The indicator 675 may include a visual indicator window 690 for viewing the indicator 675 that indicates RF/EM shielding by a color change, or other visual cue. Behind the shielding layer, there may be a series of conductive gaskets (not visible in FIG. 6) in the side/sill channels and on the underside of the pass-through plate. Having such a series of conductive gaskets as disclosed may create a conductive envelope, thereby shielding the window from the radio frequency and electromagnetic interference at an attenuation of at least about 30 dB at a frequency of at least about 10 KHz.

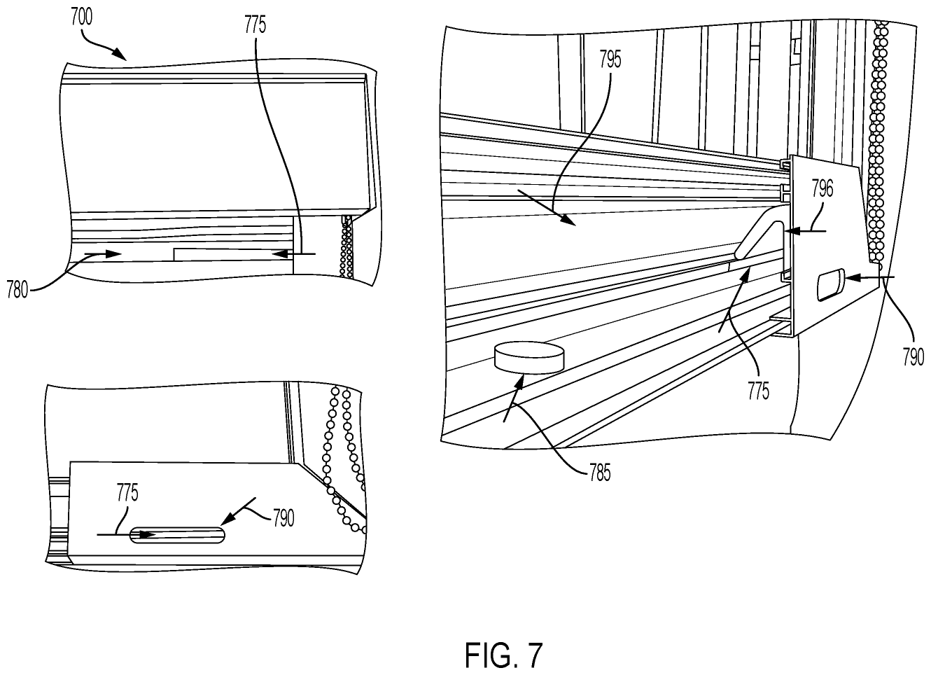

FIG. 7 depicts various view of the disclosed RF/EM interference shielding window shade in an open position where the shade is rolled up into the roller tube (hidden behind valance). FIG. 7 shows an indicator 775 located right below the valance and engaging steel rod 780. The steel rod 780 may not be visible and may be encapsulated in a hem of window fabric. In this embodiment, the indicator near the valance is green, indicating that the RF/EM interference shielding window shade 700 is in an open position. Similarly, FIG. 7 shows an indicator located in the lower portion of the system that is now red, indicating that the RF/EM interference shielding window shade 700 is in an open position and a lack of RF/EM shielding protection. FIG. 7 also shows a sill conductive gasket 795 for preventing leakage at the window sill. The sill conductive gasket 795 may be configured to fit into the sill of the window. The sill channel may include a bell-shaped conductive gasket 795 as well as a c-shaped conductive gasket 796. Having this combination of gasket profiles may enable engagement and disengagement of the steel rod 780 with the magnets 785, while maintaining full contact between the conductive gasketing 795, 796 and conductive shade material (not pictured). Additionally, FIG. 7 depicts magnet 785, which may interact with a steel rod to either trigger indicator 775 or to simply secure the RF/EM interference shielding window shade 700 in the closed position, thereby shielding against RF/EM interference.

In some embodiments, the sill conductive fabric gasket 795, 796 of a disclosed system may contain a polymer including silicone, polyethylene, a natural rubber, a neoprene, a nitrile, a fluoropolymer, a PTFE, a polyether ether ketone, a cellulose, a mylar polyester, a polycarbonate, a polytetrafluoroethylene, and combinations thereof. The sill conductive fabric gasket 795, 796 may contain a metal comprising silver, copper, gold, nickel, nickel-graphite, silver coated copper, silver coated aluminum, aluminum, silver coated glass, nickel coated aluminum, nickel coated copper, nickel coated glass, and combinations thereof. The sill conductive fabric gasket 795, 796 may include a length ranging from about 6 inches to about 120 inches. The sill conductive fabric gasket 795, 796 may include a width ranging from about 1 inch to about 12 inches. The sill conductive fabric gasket 795, 796 may include a thickness ranging from about 0.1 inch to about 6 inches.

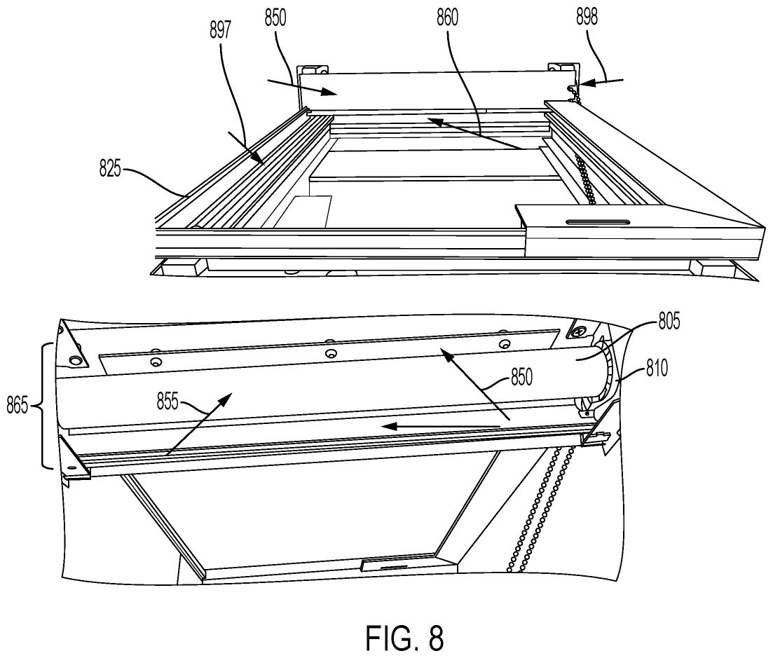

FIG. 8 illustrates an inverted view and a top view of an RF/EM interference shielding window shade 800 with the top and front fascia removed so that the roller tube 805, rolled up shade material 855, and pass-through plate 850 are viewable. As shown in FIG. 8, the conductive gasket 860 for the pass-through plate is viewable through the bottom of the pass-through plate 850. The pass-through plate 850 may have relief cuts 898 for providing for chain operation and sealing from the conductive gasket 860. A left side channel 825 may include a conductive gasket 897. In FIG. 8, the left side channel 825 does not have the opposing cap installed to provide for a better view of the profile of conductive gasket 897. The right side channel and sill channel of the RF/EM interference shielding window shade, as shown in FIG. 8, does contain conductive gasketing. In the top view of FIG. 8, portions of the pass-through plate 850 are visible, but pass-through plate slot and gasket are not visible. The roller tube 805 and clutch 810 mechanism and shade material 855 are visible.

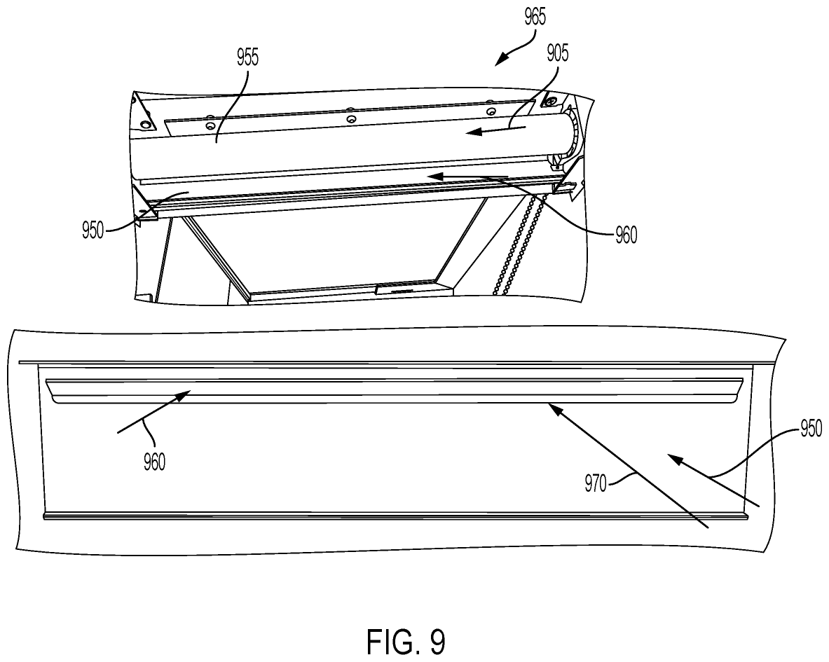

FIG. 9 illustrates a top view of an RF/EM interference shielding window shade 965 with the top and front fascia removed and an unobstructed view of a pass-through plate 950, the roller tube 905 containing the shade material 955, and the conductive gasket 960 for the pass-through plate 950. A top view, as shown in FIG. 9, shows how the pass-through plate 950 may be obstructed by a roller mechanism. In an unobstructed view of the pass-through plate 950 shown in FIG. 9, a slot (covered by conductive gasket 960) may be milled in the pass-through plate 950 and the conductive gasket 960 may be inserted. In some embodiments, a conductive material (e.g., conductive fabric) (not shown) may make contact with the conductive gasket 960 in the slot of the pass-through plate during shade operation.

Disclosed RF/EM interference shielding window shades may incorporate various conductive gaskets having any number of profiles, shapes, colors, and sizes, as is shown in FIG.

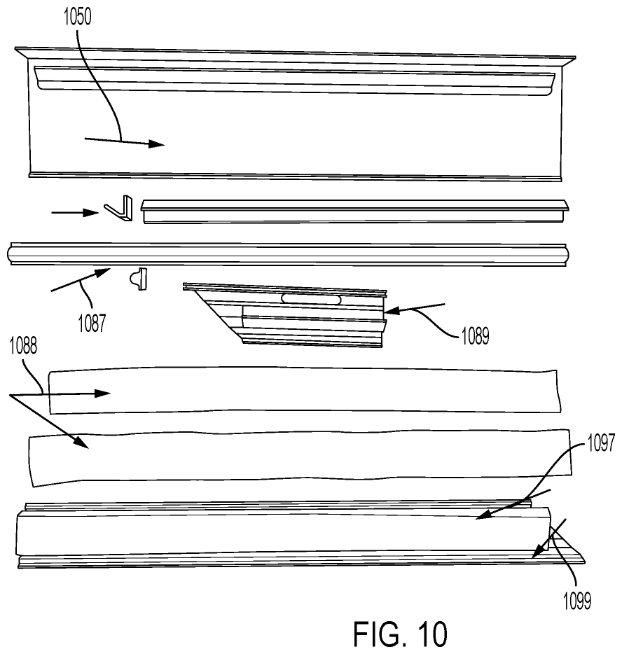

10. FIG. 10 also depicts a top view of a pass-through plate 1050. For example, FIG. 10 shows a bell-shaped conductive gasket 1087, a c-shaped conductive gasket 1089, a conductive gasket 1097 for a side channel 1099, and conductive fabric gasketing 1088.

### EXAMPLES

### Example 1. Gasketing

Conductive gaskets were needed and careful consideration was given to the plane in which the gaskets were installed. A D-shaped gasket was placed on side and sill channels, butt joined, and NiCu rip stop tape was used to join bottom of side channel gaskets to each side of the sill channel gasket. C-shaped gaskets were placed on side channels and tied into bell shaped sill channel. The bell shape on the sill channel provided a more reliable transition for the RF/EM interference shielding window shade bar to slide up and down onto the magnets.

Milling out the mole hair channels on the commercially available side and sill channels was done to provide more space for adjustment of gasket placement or enable the use of wider gaskets after three rounds of trial and error. Soft gasket material/foam or gasket profiles such as the C-shaped gasket having easier compression is useful to permit the RF/EM interference shielding window shade and bar to travel downward without snagging, while still providing enough pressure to create a shielded envelope once the bar reached the bottom of the RF/EM interference shielding window shade assembly.

To make full-width gaskets in the side and sill channels, a first step was done to mill out additional extrusion components on the side and sill channels to accept full-width gaskets. In some instances, the bottom gasket could not be the same shape as the side gaskets as the RF/EM interference shielding window shade bar would need a less constricted path to travel in and out of the sill channel. It may be useful for the sill channel gasket to be of substantially the same height/thickness as the side channel gaskets to ensure the conductive envelope is achieved. Clearance beneath the sill channel gasket is also useful to give the flat bar enough room and a forward angle to the magnets in the sill channel to further improve reliability and keep all the gaskets in the same plane.

To support positive engagement of the steel RF/EM interference shielding window shade bar with the magnets, a conductive gasket is placed in the top of the sill channel. The conductive gasket may have the same height/thickness as the side channel gaskets, but may require a differently shaped profile to enable a path for the steel shade bar to engage with the magnets in the bottom of the sill channel. For all full width gaskets, we used a much softer foam than the foam used on commercially available conductive gaskets. In some embodiments, gaskets are made from conductive material to line the inner window side and sill channels. Conductive material may also line side and sill channels. Additional gasketing may be placed in these channels to cover installation hardware or to mitigate potential signal leakage between any miters (e.g., 45 degree miters) between pieces.

### Example 2: Physical Engagement of the RF/EM Interference Shielding Window Shade Bar in the Sill Channel

Positive, physical engagement of the RF/EM interference shielding window shade bar and shade material into the sill channel was considered for conductivity and consumer confidence. Magnets were added to the sill channel, and the aluminum shade bar was replaced first by a piece of threaded rod (e.g., ⅜″ piece), permitting the new threaded rod shade bar to positively engage via magnetic attraction within the sill channel. Round threaded rod presented further challenges with moving between the side channel gaskets, as the round profile created clearance and friction issues with the shade material traveling downward from the roller tube to the sill channel.

The threaded rod was replaced with steel bar stock, which provided a thinner shade bar moving between the side channel gaskets, and into the sill channel. Due to the need to use a flat bar to minimize friction and promote consistent operation, the height of the steel bar presented issues with getting the shade bar and conductive shade material pulled forward towards the window side of the shade assembly to increase the pressure of contact of the conductive shade material onto the conductive gaskets—see gasketing notes above-this challenge resulted in the fabrication of a ‘wedge’ shaped gasket and additional gasket combinations with the goal of creating positive engagement and disengagement of the steel shade bar with the magnets in the sill channel. With full width conductive gaskets in place, there was too much friction in the side channel gaskets between the shade material and the gaskets due to the thickness of the steel shade bar, resulting in the need to reduce the profile of the steel bar on the outermost part of the bar (e.g., outermost ˜2 inches) on each side to create a thinner surface and result in less friction/drag during downward operation of the shade.

A visual red/green indicator was added via a slot (e.g., ⅜″×2″ slot, approx.) on each end of the sill channel cover plate. A red stripe was further added directly behind each slot (e.g., ⅜″×2″ slot) in the corresponding area on the sill channel. And a green painted rectangle was added on the left and right bottom corners of the shade bar pocket, to create a visual ‘green’ indicator when the shade material reached the bottom of the sill channel on each side. This change, coupled with the positive audible/tactile engagement of the steel shade bar with the magnets, provided a second indication of positive engagement/operation to the user.

### Example 3: Roller Tube Mechanism and Spacing

The standard spacing of the roller tube and the gap between the roller tube and standard ‘as-installed’ position of the side channels on a typical/commercially available roller shade assembly resulted in a significant gap between components that needed to be addressed. We created a pass-through slotted plate for conductive shade material to travel through and capture it in the side channels with conductive contact between shade material and gasketing. The slot in the pass-through slotted plate needed to have a conductive gasket in the same plane as the side channel gaskets. Accordingly, we fabricated an inverted C-shaped gasket and installed it in the pass-through slotted channel so the conductive shade material would be in contact with the gasket. We also fabricated the steel shade bar to be wider than the slotted channel to prevent the user from pulling the shade material completely up through the slot, thus, creating a ‘capture’ or safety stop.

### Example 4: Side and Sill Channel Installation Method/Angles

The recommended 90 degree butt joint installation method would have left a

number of significant openings between the side and sill channels. As such, we mitered the side and sill channels to meet at 45 degree angles for future welding or use of a small additional conductive gasket(s), conductive caulk, or other conductive materials such as copper wool, aluminum foil material, etc.

The figures and descriptions provided herein may have been simplified to illustrate aspects that are relevant for a clear understanding of the herein described devices, systems, and methods, while eliminating, for the purpose of clarity, other aspects that may be found in typical similar devices, systems, and methods. Those of ordinary skill may recognize that other elements and/or operations may be desirable and/or necessary to implement the devices, systems, and methods described herein. But because such elements and operations are well known in the art, and because they do not facilitate a better understanding of the present disclosure, a discussion of such elements and operations may not be provided herein. However, the present disclosure is deemed to inherently include all such elements, variations, and modifications to the described aspects that would be known to those of ordinary skill in the art.

The terminology used herein is for the purpose of describing particular example embodiments only and is not intended to be limiting. For example, as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc., may be used herein to describe various elements, components, regions, layers and/or sections, these elements, components, regions, layers and/or sections should not be limited by these terms. These terms may be only used to distinguish one element, component, region, layer or section from another element, component, region, layer or section. That is, terms such as “first,” “second,” and other numerical terms, when used herein, do not imply a sequence or order unless clearly indicated by the context. Reference in the specification to “one implementation” or “an implementation” means that a particular feature, structure, or characteristic described in connection with the implementation is included in at least one implementation of the disclosure. The appearances of the phrase “in one implementation,” “in some implementations,” “in one instance,” “in some instances,” “in one case,” “in some cases,” “in one embodiment,” or “in some embodiments” in various places in the specification are not necessarily all referring to the same implementation or embodiment.

Finally, the above descriptions of the implementations of the present disclosure have been presented for the purposes of illustration and description. It is not intended to be exhaustive or to limit the present disclosure to the precise form disclosed. Many modifications and variations are possible in light of the above teaching. It is intended that the scope of the present disclosure be limited not by this detailed description, but rather by the claims of this application. As will be understood by those familiar with the art, the present disclosure may be embodied in other specific forms without departing from the spirit or essential characteristics thereof. Accordingly, the present disclosure is intended to be illustrative, but not limiting, of the scope of the present disclosure, which is set forth in the following claims.

What is claimed is:

1. A radio frequency and electromagnetic interference shielding window shade comprising:
(a) a roller tube comprising a roller shade clutch and an end plug connected through a cylindrical body, the clutch configured to rotate the roller tube;
(b) a shade material extending between a first end attached to the roller tube and a second end extending away from the roller tube, wherein the shade material is configured to rotate about the cylindrical body of the roller tube to roll or unroll the shade, the shade material comprising:
a shielding layer attached to a side of a base layer and comprising a conductive material,
wherein unrolling the shade material from the roller tube covers at least a portion of a window, thereby shielding the window from the radio frequency and electromagnetic interference at an attenuation of at least about 30 dB at a frequency of at least about 10 KHz.

2. The radio frequency and electromagnetic interference shielding window shade according to claim 1, wherein the shade material further comprises at least one of:
a plurality of base layers; and
a plurality of shielding layers.

3. The radio frequency and electromagnetic interference shielding window shade according to claim 1,
wherein the shade material further comprises a second shielding layer, wherein the base layer is sandwiched between the shielding layer and the second shielding layer.

4. The radio frequency and electromagnetic interference shielding window shade according to claim 1, wherein the shade material further comprises a second base layer, wherein the shielding layer is sandwiched between the base layer and the second base layer.

5. The radio frequency and electromagnetic interference shielding window shade according to claim 1, wherein at least one of:
the radio frequency and electromagnetic interference attenuation ranges from about 30 dB to about 120 dB, and
the frequency ranges from about 10 KHz to about 100 GHz.

6. The radio frequency and electromagnetic interference shielding window shade according to claim 1, wherein at least one of:
the base layer comprises a nylon 6, a nylon 66, a polyester, a polyethylene, a polyurethane, a fluorocarbon rubber, a viton, a carbon fiber, and combinations thereof, and
the conductive material comprises an intrinsically conductive polymer, a metal, a carbon, a metal oxide, a polyaniline, a graphene, a carbon nanotube, a silver, a nickel, a copper, and a combination thereof.

7. The radio frequency and electromagnetic interference shielding window shade according to claim 1, further comprising:
a pass-through plate positioned directly below the roller tube, the pass-through plate comprising:
a horizontal flat plate spanning a length and a width of the roller tube; and
a slot configured to permit passage of the shade material as it unrolls from the roller tube to extend away from the roller tube, thereby covering at least the portion of the window.

8. The radio frequency and electromagnetic interference shielding window shade according to claim 7, further comprising:
a conductive gasket incorporated into the slot of the pass-through plate.

9. The radio frequency and electromagnetic interference shielding window shade according to claim 8, wherein the conductive gasket comprises:
(a) a polymer comprising silicone, polyethylene, a natural rubber, a neoprene, a nitrile, a fluoropolymer, a PTFE, a polyether ether ketone, a cellulose, a mylar polyester, a polycarbonate, a polytetrafluoroethylene, and combinations thereof; and
(b) a metal comprising silver, copper, gold, nickel, nickel-graphite, silver coated copper, silver coated aluminum, aluminum, silver coated glass, nickel coated aluminum, nickel coated copper, nickel coated glass, and combinations thereof,
wherein at least one of:
the conductive gasket is configured to make contact with the shade material as it moves towards and away from the roller tube, and
the conductive gasket has a cross-section comprising a c-shape, a bell shape, a u-shape, a circle, a triangle, any polygon, and combinations thereof.

10. A system for shielding a window from radio frequency and electromagnetic interference, the system comprising:
(a) a radio frequency and electromagnetic interference shielding window shade comprising:
(i) a roller tube comprising a roller shade clutch and an end plug connected through a cylindrical body, the clutch configured to rotate the roller tube;
(ii) a shade material extending between a first end attached to the roller tube and a second end extending away from the roller tube, wherein the shade material is configured to rotate about the cylindrical body of the roller tube to roll or unroll the shade, the shade material comprising a shielding layer attached to a side of a base layer and comprising a conductive material; and
(b) a channel conductive fabric gasket configured to fit into at least one side channel of the window,
wherein unrolling the shade material from the roller tube covers at least a portion of a window, thereby shielding the window from radio frequency and electromagnetic interference at an attenuation of at least about 30 dB at a frequency of at least about 10 KHz.

11. The system for shielding the window from radio frequency and electromagnetic interference according to claim 10, further comprising:
two channel conductive fabric gaskets configured to fit into each side channel of the window.

12. The system for shielding the window from radio frequency and electromagnetic interference according to claim 10, wherein the channel conductive fabric gasket comprises:
(a) a polymer comprising silicone, polyethylene, a natural rubber, a neoprene, a nitrile, a fluoropolymer, a PTFE, a polyether ether ketone, a cellulose, a mylar polyester, a polycarbonate, a polytetrafluoroethylene, and combinations thereof; and
(b) a metal comprising silver, copper, gold, nickel, nickel-graphite, silver coated copper, silver coated aluminum, aluminum, silver coated glass, nickel coated aluminum, nickel coated copper, nickel coated glass, and combinations thereof.

13. The system for shielding the window from radio frequency and electromagnetic interference according to claim 10, further comprising:
a sill conductive fabric gasket configured to fit into a sill of the window.

14. The system for shielding the window from radio frequency and electromagnetic interference according to claim 13, wherein the sill conductive fabric gasket comprises:
(a) a polymer comprising silicone, polyethylene, a natural rubber, a neoprene, a nitrile, a fluoropolymer, a PTFE, a polyether ether ketone, a cellulose, a mylar polyester, a polycarbonate, a polytetrafluoroethylene, and combinations thereof; and
(b) a metal comprising silver, copper, gold, nickel, nickel-graphite, silver coated copper, silver coated aluminum, aluminum, silver coated glass, nickel coated aluminum, nickel coated copper, nickel coated glass, and combinations thereof.

15. The system for shielding the window from radio frequency and electromagnetic interference according to claim 13, wherein at least one of:
the sill conductive fabric gasket comprises:
a length ranging from about 6 inches to about 120 inches;
a width ranging from about 1 inch to about 12 inches; and
a thickness ranging from about 0.1 inch to about 6 inches, and the channel conductive fabric gasket comprises:
a length ranging from about 6 inches to about 120 inches;
a width ranging from about 1 inch to about 12 inches; and
a thickness ranging from about 0.1 inch to about 6 inches.

16. The system for shielding the window from radio frequency and electromagnetic interference according to claim 10, wherein at least one of:
the base layer comprises a nylon 6, a nylon 66, a polyester, a polyethylene, a polyurethane, a fluorocarbon rubber, a viton, a carbon fiber, and combinations thereof, and
the conductive material comprises an intrinsically conductive polymer, a metal, a carbon, a metal oxide, a polyaniline, a graphene, a carbon nanotube, a silver, a nickel, a copper, and a combination thereof.

17. The system for shielding the window from radio frequency and electromagnetic interference according to claim 10, wherein at least one of:
the RF/EM attenuation ranges from about 30 dB to about 120 dB, and
the frequency ranges from about 10 KHz to about 100 GHz.

18. The system for shielding the window from radio frequency and electromagnetic interference according to claim 10, wherein the shade material further comprises at least one of:
a plurality of base layers; and
a plurality of shielding layers.

19. The system for shielding the window from radio frequency and electromagnetic interference according to claim 10, further comprising:
a pass-through plate positioned directly below the roller tube, the pass-through plate comprising:
a horizontal flat plate spanning a length and a width of the roller tube; and
a slot configured to permit passage of the shade material as it unrolls from the roller tube to extend away from the roller tube, thereby covering at least the portion of the window.

20. The system for shielding the window from radio frequency and electromagnetic interference according to claim 10, further comprising:
a steel rod attached to a bottom end of the shade material; and
an indicator configured to interact with the steel rod as the shade material extends away from the roller tube to cover the window and to visually indicate coverage of the window by the shade material.
